(19) United States
(12) Patent Application Publication
(10) Pub. No.: US 2026/0291182 A1
(43) Pub. Date: Sep. 24, 2026

(54) COMPOSITE SUBSTRATE AND METHOD OF PRODUCING COMPOSITE SUBSTRATE

(71) Applicant: NGK Corporation, Nagoya-shi (JP)

(72) Inventors: Jungo KONDO, Miyoshi-shi (JP); Kentaro TANI, Nagoya-shi (JP); Tetsuya EJIRI, Kasugai-shi (JP)

(21) Appl. No.: 19/670,092

(22) Filed: May 7, 2026

Related U.S. Application Data
(63) Continuation of application No. PCT/JP2024/040057, filed on Nov. 12, 2024.

(30) Foreign Application Priority Data
Nov. 14, 2023 (JP) 2023-193964
Jun. 24, 2024 (JP) 2024-101481

(51) Int. Cl. H01S 5/183; H01S 5/065

(52) U.S. Cl. CPC H01S 5/183; H01S 5/0657

(57) ABSTRACT

A composite substrate includes: a wavelength conversion layer configured to convert incident light into light having a different wavelength; and a multilayer film arranged adjacent to the wavelength conversion layer, wherein the multilayer film includes a plurality of refractive index layers, wherein the wavelength conversion layer has an end portion in a thickness direction on a side on which the multilayer film is arranged, and, in the end portion of the wavelength conversion layer in the thickness direction, a region in which an abundance of an inert gas atom is 0.5 at % or more is formed, and wherein, in the multilayer film, a first refractive index layer is positioned closest to the wavelength conversion layer among the plurality of refractive index layers, and an abundance of the inert gas atom in the first refractive index layer is less than 0.5 at %.

### CROSS-REFERENCE TO RELATED APPLICATIONS

This application is a continuation under 35 U.S.C. 120 of International Application PCT/JP2024/040057 having the International Filing Date of Nov. 12, 2024 and having the benefit of the earlier filing dates of Japanese Application No. 2023-193964, filed on Nov. 14, 2023 and Japanese Application No. 2024-101481, filed on Jun. 24, 2024. Each of the identified applications is fully incorporated herein by reference.

### BACKGROUND OF THE INVENTION

### 1. Field of the Invention

The present disclosure relates to a composite substrate and a method of producing a composite substrate.

### 2. Description of the Related Art

Solid-state lasers capable of outputting short-pulse light are widely used. A laser having extremely high optical output at an even shorter pulse width is expected to be applied in sensing, precision processing, medicine, and various other fields. As a laser of this kind, as disclosed in, for example, Patent Literature 1, a laser structure that is a combination of a semiconductor laser, a solid-state laser gain medium layer capable of functioning as a wavelength conversion layer, and a saturable absorber has been proposed.

### CITATION LIST

### Patent Literature

[PTL 1] WO 2020/166420 A1

### SUMMARY OF THE INVENTION

In the laser structure as described above, a light reflection characteristic at an interface of the wavelength conversion layer may significantly affect the performance of the laser.

The present disclosure has been made in view of the foregoing, and has a primary object to provide a composite substrate excellent in reflection characteristic at an interface of a wavelength conversion layer.
1. According to an embodiment of the present disclosure, there is provided a composite substrate including: a wavelength conversion layer configured to convert incident light into light having a different wavelength; and a multilayer film arranged adjacent to the wavelength conversion layer, wherein the multilayer film includes a plurality of refractive index layers, wherein the wavelength conversion layer has an end portion in a thickness direction on a side on which the multilayer film is arranged, and, in the end portion of the wavelength conversion layer in the thickness direction, a region in which an abundance of an inert gas atom is 0.5 at % or more is formed, and wherein, in the multilayer film, a first refractive index layer is positioned closest to the wavelength conversion layer among the plurality of refractive index layers, and an abundance of the inert gas atom in the first refractive index layer is less than 0.5 at %.
2. In the multilayer film of the composite substrate according to the above-mentioned item 1, the plurality of refractive index layers included in the multilayer film may each have a refractive index of from 1.3 to 2.4, and the multilayer film may include one or more refractive index layers each having a refractive index of 2.1 or more.
3. In the composite substrate according to the above-mentioned item 1 or 2, the wavelength conversion layer and the first refractive index layer may be joined to each other.
4. In the composite substrate according to any one of the above-mentioned items 1 to 3, the inert gas atom may be argon or xenon.
5. In the multilayer film of the composite substrate according to any one of the above-mentioned items 1 to 4, a difference between a highest refractive index and a lowest refractive index among refractive indices of the plurality of refractive index layers may be 0.5 or more.
6. In the composite substrate according to any one of the above-mentioned items 1 to 5, the wavelength conversion layer may be selected from a doped yttrium aluminum garnet crystal, a doped yttrium vanadate crystal, and a doped yttrium lithium fluoride crystal.
7. In the composite substrate according to any one of the above-mentioned items 1 to 6, a material for forming each of the plurality of refractive index layers included in the multilayer film may be selected from silicon oxide, tantalum oxide, titanium oxide, aluminum oxide, yttrium oxide, zirconium oxide, hafnium oxide, lanthanum oxide, cerium oxide, tungsten oxide, zinc oxide, niobium oxide, and magnesium oxide.
8. In the composite substrate according any one of the above-mentioned items 1 to 7, a material for forming the first refractive index layer may be selected from tantalum oxide, titanium oxide, aluminum oxide, yttrium oxide, zirconium oxide, hafnium oxide, lanthanum oxide, cerium oxide, tungsten oxide, zinc oxide, niobium oxide, and magnesium oxide.
9. In the composite substrate according any one of the above-mentioned items 1 to 8, the end portion of the wavelength conversion layer in the thickness direction may include a third layer, a second layer, and a first layer in the stated order from the multilayer film side, and an abundance of the inert gas atom in the second layer may be larger than an abundance of the inert gas atom in the third layer.
10. In the composite substrate according to the above-mentioned item 9, the third layer may be an amorphous layer.
11. In the composite substrate according to any one of the above-mentioned items 1 to 10, the first refractive index layer may have a refractive index that is uniform in the thickness direction.
12. In the composite substrate according to any one of the above-mentioned items 1 to 11, two neighboring refractive index layers included in the multilayer film may have refractive indices different from each other.
13. In the composite substrate according to any one of the above-mentioned items 1 to 12, the plurality of refractive index layers included in the multilayer film each have a thickness of 50 nm or more and 300 nm or less.
14. The composite substrate according to any one of the above-mentioned items 1 to 13 may include the wavelength conversion layer, the multilayer film, and a surface emitting laser substrate in the stated order.
15. The composite substrate according to any one of the above-mentioned items 1 to 14 may include the wavelength conversion layer, the multilayer film, and a saturable absorber layer in the stated order.
16. According to another embodiment of the present disclosure, there is provided a composite substrate including in the following order: a surface emitting laser substrate; a wavelength conversion layer configured to convert incident light into light having a different wavelength; and a saturable absorber layer, wherein the composite substrate further includes a multilayer film arranged adjacent to the wavelength conversion layer, in at least one of a space between the surface emitting substrate and the wavelength conversion layer or a space between the saturable absorber layer and the wavelength conversion layer, wherein the multilayer film includes a plurality of refractive index layers, wherein the wavelength conversion layer has an end portion in a thickness direction on a side on which the multilayer film is arranged, and, in the end portion of the wavelength conversion layer in the thickness direction, a region in which an abundance of an inert gas atom is 0.5 at % or more is formed, and wherein, in the multilayer film, a first refractive index layer is positioned closest to the wavelength conversion layer among the plurality of refractive index layers, and an abundance of the inert gas atom in the first refractive index layer is less than 0.5 at %.
17. According to an embodiment of the present disclosure, there is provided a laser structure including the composite substrate of any one of the above-mentioned items 1 to 16.
18. According to an embodiment of the present disclosure, there is provided a method of producing the composite substrate of any one of the above-mentioned items 1 to 17, the method including in the following order: preparing a laminated structure having a plurality of refractive index layers; subjecting each of a surface of a wavelength conversion material substrate and a surface of the laminated structure to activation treatment; forming, on the surface of the laminated structure, a deposition layer containing a component for forming the wavelength conversion material substrate by subjecting the surface of the wavelength conversion material substrate to sputtering treatment; and joining the laminated structure and the wavelength conversion material substrate to each other.
19. In the method of producing the composite substrate according to the above-mentioned item 18, a length of time of the sputtering treatment may be from 3 minutes to 10 minutes.

According to the embodiment of the present disclosure, it is possible to provide the composite substrate excellent in reflection characteristic at the interface of the wavelength conversion layer.

### BRIEF DESCRIPTION OF THE DRAWINGS

FIG. 1 is a schematic sectional view for illustrating a schematic configuration of a composite substrate according to one embodiment of the present disclosure.

FIG. 2 is a schematic partially enlarged sectional view for illustrating an example of a state of each end portion of a wavelength conversion layer in a thickness direction.

FIG. 3A is a view for illustrating an example of a production process for a composite substrate according to one embodiment.

FIG. 3B is a view subsequent to FIG. 3A.

FIG. 3C is a view subsequent to FIG. 3B.

FIG. 3D is a view subsequent to FIG. 3C.

FIG. 4 is a graph for showing a simulation result of a reflection characteristic of a multilayer film in Example 1.

FIG. 5 is a graph for showing a simulation result of a reflection characteristic of a multilayer film in Comparative Example 1.

FIG. 6 is a graph for showing a simulation result of a reflection characteristic of a multilayer film in Example 2.

FIG. 7 is a graph for showing a simulation result of a reflection characteristic of a multilayer film in Example 3.

FIG. 8 is a graph for showing a simulation result of a reflection characteristic of a multilayer film in Example 4.

FIG. 9 is a graph for showing a simulation result of a reflection characteristic of a multilayer film in Example 5.

FIG. 10 is a graph for showing a simulation result of a reflection characteristic of a multilayer film in Example 6.

FIG. 11 is a graph for showing a simulation result of a reflection characteristic of a multilayer film in Example 7.

### DESCRIPTION OF THE EMBODIMENTS

Embodiments of the present disclosure are described below with reference to the drawings. However, the present disclosure is not limited to those embodiments. In order to further clarify the description, the width, thickness, shape, and the like of each portion may be schematically illustrated in the drawings as compared to the embodiments, but the illustration is merely an example and does not limit the interpretation of the present disclosure. In addition, in the drawings, the same or similar components are denoted by the same reference symbols, and repetitive description thereof may be omitted.

### [Composite Substrate]

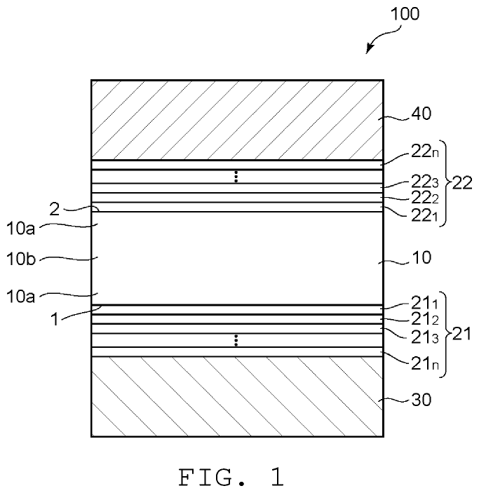

FIG. 1 is a schematic sectional view for illustrating a schematic configuration of a composite substrate according to one embodiment of the present disclosure. For easy viewing, hatching of some members is omitted in FIG. 1.

A composite substrate 100 includes: a wavelength conversion layer 10 which has a first main surface 1 and a second main surface 2 facing each other and which converts incident light into light having a different wavelength; a first multilayer film 21 arranged adjacent to the first main surface 1 of the wavelength conversion layer 10; a second multilayer film 22 arranged adjacent to the second main surface 2 of the wavelength conversion layer 10; a substrate 30 arranged on the first multilayer film 21 side of the wavelength conversion layer 10; and a function layer 40 arranged on the second multilayer film 22 side of the wavelength conversion layer 10.

The composite substrate 100 is applicable to, for example, a laser device. The substrate 30 is a substrate for forming, for example, a surface emitting laser (e.g., a vertical cavity surface emitting laser (VCSEL) or a vertical external cavity surface emitting laser (VECSEL)). The wavelength conversion layer 10 is capable of converting, for example, a first wavelength of laser light that enters from the first main surface 1 side thereof into a second wavelength. Although not shown, a cavity structure portion may be arranged in the substrate 30.

As the substrate for forming a surface emitting laser, for example, a gallium arsenide substrate, an indium phosphide substrate, or a gallium nitride substrate is used. The substrate for forming a surface emitting laser has a thickness of, for example, from 100 μm to 1,000 μm.

The wavelength conversion layer 10 is formed of any appropriate wavelength conversion material capable of converting incident light into light having a different wavelength. As a material for forming the wavelength conversion layer 10, a doped yttrium aluminum garnet (hereinafter referred to as “YAG”) crystal is typically used. Specific examples of the doped YAG crystal include an YAG crystal doped with Yb³⁺ (Yb:YAG) and an YAG crystal doped with Nd³⁺ (Nd:YAG). As another material for forming the wavelength conversion layer 10, for example, a doped yttrium vanadate (hereinafter referred to as “YVO₄”) crystal or a doped yttrium lithium fluoride (hereinafter referred to as “YLF”) crystal is used. Specific examples of the doped YVO₄ crystal include an YVO₄ crystal doped with Yb³⁺ (Yb:YVO₄) and an YVO₄ crystal doped with Nd³⁺ (Nd:YVO₄). Specific examples of the doped YLF crystal include an YLF crystal doped with Yb³⁺ (Yb:YLF) and an YLF crystal doped with Nd³⁺ (Nd:YLF). In addition, examples of another material for forming the wavelength conversion layer 10 include Nd:glass, Yb:FAP, Yb:SFAP, Yb:glass, Yb:KYW, Yb:BCBF, Yb:YCOB, Yb:GdCOB, and Yb:YAB. Of those, a doped YAG crystal, a doped YVO₄ crystal, and a doped YLF crystal are preferred as another material for forming the wavelength conversion layer 10. Those materials are each capable of exhibiting similar adhesion to, for example, an adjacent layer. The wavelength conversion layer 10 has a thickness of, for example, from 10 μm to 600 μm.

The first multilayer film 21 is a laminate of a plurality of refractive index layers. In the illustrated example, the first multilayer film 21 includes “n” layers from a first refractive index layer 21₁, a second refractive index layer 21₂, a third refractive index layer 21₃, and an n-th refractive index layer 21ₙ from the wavelength conversion layer 10 side. Specifically, the refractive index layer positioned closest to the wavelength conversion layer 10 is the first refractive index layer 21₁, and the refractive index layer positioned closest to the substrate 30 is the n-th refractive index layer 21ₙ. A number represented by “n” is, for example, from 10 to 50, preferably from 15 to 40. Each of the layers included in the first multilayer film 21 has a thickness of, for example, 50 nm or more and 300 nm or less.

The first multilayer film 21 includes a plurality of refractive index layers having different refractive indices, and includes high refractive index layers each having a relatively high refractive index and low refractive index layers each having a relatively low refractive index. For example, two neighboring layers included in the first multilayer film 21 have refractive indices different from each other, with one of the two being a high refractive index layer and the other being a low refractive index layer. In addition, for example, at least a part of the first multilayer film 21 may be formed by alternately laminating a high refractive index layer and a low refractive index layer. As a specific example, the second refractive index layer 21₂ may have a lower or higher refractive index than those of the first refractive index layer 21₁ and the third refractive index layer 21₃. In this case, the refractive index of the first refractive index layer 21₁ and the refractive index of the third refractive index layer 21₃ may be substantially the same as each other or may differ from each other.

The first multilayer film 21 is formed so as to be capable of transmitting light having the first wavelength that has been emitted from the substrate 30 side. Specifically, the first multilayer film 21 is formed so as to be capable of functioning as a transmissive layer or an antireflection layer with respect to light having the first wavelength. From the viewpoint of, for example, improving light utilization efficiency, the first multilayer film 21 is also formed so as to be capable of suppressing emission of light having the second wavelength from the wavelength conversion layer 10 to the substrate 30 side. Specifically, the first multilayer film 21 is formed so as to be capable of functioning as a reflective layer with respect to light having the second wavelength. Those functions of the first multilayer film 21 may be achieved by, for example, adjusting the number (“n” described above) of refractive index layers for forming the first multilayer film 21, the thicknesses of the respective refractive index layers, and the refractive indices of the respective refractive index layers.

Laser light that has entered from the first main surface 1 (substrate 30) side may be emitted from the second main surface 2 side. For example, light having the second wavelength having been converted by the wavelength conversion layer 10 may be transmitted through the function layer 40 to be emitted. The function layer 40 is capable of functioning as, for example, a saturable absorber layer. In this case, the function layer (saturable absorber layer) 40 may be formed typically of a material, such as an YAG crystal doped with Cr⁴⁺ (Cr:YAG) or an YAG crystal doped with V³⁺ (V:YAG). The function layer (saturable absorber layer) 40 has a thickness of, for example, from 10 μm to 600 μm.

The second multilayer film 22 is a laminate of a plurality of refractive index layers. In the illustrated example, the second multilayer film 22 includes “n” layers from a first refractive index layer 22₁, a second refractive index layer 22₂, a third refractive index layer 22₃, . . . , and an n-th refractive index layer 22ₙ from the wavelength conversion layer 10 side. Specifically, the layer positioned closest to the wavelength conversion layer 10 is the first refractive index layer 22₁, and the layer positioned closest to the function layer 40 is the n-th refractive index layer 22ₙ. A number represented by “n” is, for example, from 10 to 50, preferably from 15 to 40. Each of the refractive index layers included in the second multilayer film 22 has a thickness of, for example, 50 nm or more and 300 nm or less.

The second multilayer film 22 includes a plurality of refractive index layers having different refractive indices, and includes high refractive index layers each having a relatively high refractive index and low refractive index layers each having a relatively low refractive index. For example, two neighboring layers included in the second multilayer film 22 have refractive indices different from each other, with one of the two being a high refractive index layer and the other being a low refractive index layer. In addition, for example, at least a part of the second multilayer film 22 may be formed by alternately laminating a high refractive index layer and a low refractive index layer. As a specific example, the second layer 22₂ may have a lower or higher refractive index than those of the first refractive index layer 22₁ and the third refractive index layer 22₃. In this case, the refractive index of the first refractive index layer 22₁ and the refractive index of the third refractive index layer 22₃ may be substantially the same as each other or may differ from each other.

The second multilayer film 22 is formed so as to be capable of transmitting light that has been emitted from the wavelength conversion layer 10 and that has the second wavelength. Specifically, the second multilayer film 22 is formed so as to be capable of functioning as a transmissive layer or an antireflection layer with respect to light having the second wavelength. From the viewpoint of, for example, improving light utilization efficiency, the second multilayer film 22 is also formed so as to be capable of suppressing emission of light having the first wavelength from the wavelength conversion layer 10 to the function layer 40 side. Specifically, the second multilayer film 22 is formed so as to be capable of functioning as a reflective layer with respect to light having the first wavelength. Those functions of the second multilayer film 22 may be achieved by, for example, adjusting the number (“n” described above) of refractive index layers for forming the second multilayer film 22, the thicknesses of the respective refractive index layers, and the refractive indices of the respective refractive index layers.

As described above, the first multilayer film 21 and the second multilayer film 22 (hereinafter sometimes simply referred to as “multilayer films”) are each a laminate of a plurality of refractive index layers, and may include a high refractive index layer and a low refractive index layer which have refractive indices different from each other. The refractive index of each of the refractive index layers included in each of the multilayer films (the refractive index of a material for forming each of the refractive index layers included in each of the multilayer films) is, for example, from 1.3 to 2.4, preferably from 1.4 to 2.4, more preferably from 1.45 to 2.35. The refractive index may be a value measurable with a spectroscopic ellipsometer or a spectral photometer. The refractive index of the high refractive index layer is relatively higher than the refractive index of the low refractive index layer. Specifically, the refractive index of a material for forming the high refractive index layer is higher than the refractive index of a material for forming the low refractive index layer. The refractive index of the low refractive index layer is, for example, from 1.3 to 1.8. The refractive index of the high refractive index layer is, for example, from 1.55 to 2.4.

A plurality of low refractive index layers that may be included in each of the multilayer films may have the same configuration (e.g., in terms of material and thickness) as one another, or configurations different from one another. In the same manner, a plurality of high refractive index layers that may be included in each of the multilayer films may have the same configuration (e.g., in terms of material and thickness) as one another, or configurations different from one another.

Each of the multilayer films preferably includes one or more refractive index layers each having a refractive index of 2.1 or higher. When each of the multilayer films include such refractive index layers, a desired transmission characteristic (reflection characteristic) can be satisfactorily achieved. In each of the multilayer films, a difference between a highest refractive index and a lowest refractive index among the refractive indices of the refractive index layers is preferably 0.5 or more, more preferably 0.6 or more, still more preferably 0.7 or more. From the viewpoint of satisfying the condition about the difference, each of the multilayer films preferably includes one or more refractive index layers each having a refractive index of 1.5 or less.

As a material for forming each of the refractive index layers included in each of the multilayer films, a dielectric material is typically used. Specific examples of the material for forming each of the refractive index layers included in each of the multilayer films include silicon oxide, tantalum oxide, titanium oxide, aluminum oxide, yttrium oxide, zirconium oxide, hafnium oxide, lanthanum oxide, cerium oxide, tungsten oxide, zinc oxide, niobium oxide, and magnesium oxide. Those materials may be used alone or in combination thereof (e.g., as a composite oxide). Specifically, the refractive index layer may be formed of an oxide containing at least one selected from silicon, tantalum, titanium, aluminum, yttrium, zirconium, hafnium, lanthanum, cerium, tungsten, zinc, niobium, and magnesium.

Specific examples of the material for forming the first refractive index layer included in the multilayer film include tantalum oxide, titanium oxide, aluminum oxide, yttrium oxide, zirconium oxide, hafnium oxide, lanthanum oxide, cerium oxide, tungsten oxide, zinc oxide, niobium oxide, and magnesium oxide. Those may be used alone or in combination thereof (e.g., as a composite oxide). Specifically, the first refractive index layer may be formed of an oxide containing at least one selected from tantalum, titanium, aluminum, yttrium, zirconium, hafnium, lanthanum, cerium, tungsten, zinc, niobium, and magnesium. According to such first refractive index layer, adhesiveness between the multilayer film and the wavelength conversion layer 10 can be excellent.

Each refractive index layer included in the multilayer film may be formed by any appropriate method. Each refractive index layer included in the multilayer film may be formed by, for example, physical deposition, such as sputtering or ion beam assisted deposition (IAD), chemical deposition, or an atomic layer deposition (ALD) method.

An inert gas atom is present in an end portion (hereinafter sometimes referred to as “end portion in the thickness direction”) 10a of the wavelength conversion layer 10 on each of sides on which the multilayer films are arranged. The phrase “end portion in the thickness direction” as used herein means a part having a certain thickness. Examples of the typical inert gas atom include argon and xenon. A region in which the inert gas atom is present is formed in the end portion 10a of the wavelength conversion layer 10 in the thickness direction, and the region may be formed so as to stretch over an entire surface of the wavelength conversion layer 10. For example, in the wavelength conversion layer 10, a layer in which an inert gas atom is present is formed in the end portion 10a in the thickness direction. In the region (layer) in which the inert gas atom is present, an abundance of the inert gas atom is, for example, 0.5 at % or more and 10 at % or less, and may be 0.7 at % or more.

Meanwhile, in a central portion 10b of the wavelength conversion layer 10 in the thickness direction, an inert gas atom is preferably substantially absent. An abundance of an inert gas atom in the central portion 10b of the wavelength conversion layer 10 in the thickness direction is, for example, less than 0.5 at %, and may be 0.4 at % or less.

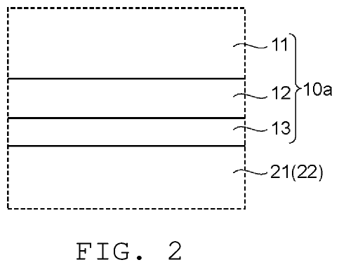

FIG. 2 is a schematic partially enlarged sectional view for illustrating an example of a state of each end portion of the wavelength conversion layer in the thickness direction. In each end portion 10a of the wavelength conversion layer 10 in the thickness direction, a third layer 13, a second layer 12, and a first layer 11 are formed in the stated order from the multilayer film 21 (22) side. For example, the third layer 13 may be an amorphous layer. The first layer 11 may be a crystalline layer. The second layer 12 may be an amorphous layer or a crystalline layer, or may be a combination thereof. The second layer 12 and the third layer 13 may contain a constituent atom of the first layer 11.

An inert gas atom may be present mainly in the second layer 12. An inert gas atom may be present in the third layer 13, or may be substantially absent in the third layer 13. For example, an abundance of an inert gas atom is larger in the second layer 12 than in the third layer 13. The abundance of an inert gas atom in the second layer 12 is, for example, 0.5 at % or more and 10 at % or less, preferably 0.7 at % or more and 4 at % or less. A lower limit value of the abundance of an inert gas atom in the third layer 13 may be 0.2 at %, preferably 0 at %. An upper limit value of the abundance of an inert gas atom in the third layer 13 may be 10 at %, preferably 3 at %. The second layer 12 and/or the third layer 13 may contain Fe and Cr.

A thickness of the second layer 12 is, for example, 0.2 nm or more, and may be 0.4 nm or more. Meanwhile, the thickness of the second layer 12 is, for example, 10 nm or less, preferably 5 nm or less. A thickness of the third layer 13 is, for example, 0.2 nm or more, and may be 0.3 nm or more. Meanwhile, the thickness of the third layer 13 is, for example, 8 nm or less, preferably 4 nm or less.

Inert gas atoms are substantially absent in the first refractive index layer of each of the multilayer films which is adjacent to the wavelength conversion layer 10, and an abundance of an inert gas atom in the first refractive index layer is, for example, less than 0.5 at %, and may be 0.4 at % or less. When the first refractive index layer which is closest to the wavelength conversion layer 10 has such configuration, for example, a component for forming the wavelength conversion layer is suppressed from mixing into the first refractive index layer, and hence the first refractive index layer can have a refractive index that is uniform in its thickness direction. Specifically, in the thickness direction of the first refractive index layer, there is substantially no difference in the refractive index of the first refractive index layer between the wavelength conversion layer 10 side and a second refractive index layer side. When the refractive index of the first refractive index layer is uniform, for example, a desired reflection characteristic can be satisfactorily achieved.

The above-mentioned abundances of an inert gas atom can be obtained by composition analysis by, for example, energy dispersive X-ray spectroscopy (EDX).

From the composite substrate 100, the function layer 40 and the second multilayer film 22 may be omitted, or the substrate 30 and the first multilayer film 21 may be omitted. In addition, although not shown, the composite substrate 100 may further include any appropriate layer. The kinds, functions, number, combination, arrangement, and the like of such layers may be appropriately set in accordance with purposes. For example, the composite substrate 100 may include another function layer (e.g., light scanner layer) arranged on the function layer 40.

The composite substrate 100 may be produced in any appropriate shape. In one embodiment, the composite substrate 100 may be produced in the form of a so-called wafer. The size of the composite substrate 100 may be appropriately set in accordance with purposes. For example, the diameter of the wafer is from 50 mm to 150 mm. In addition, for example, the diameter of the wafer is from 3 inches to 6 inches.

### [Production Method]

The above-mentioned composite substrate can be obtained by, for example, preparing a laminated structure of a plurality of refractive index layers, and joining the laminated structure and a wavelength conversion material substrate to each other.

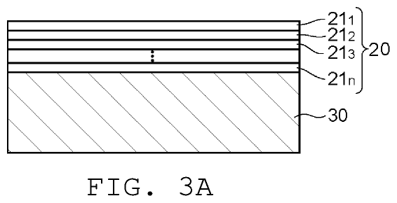

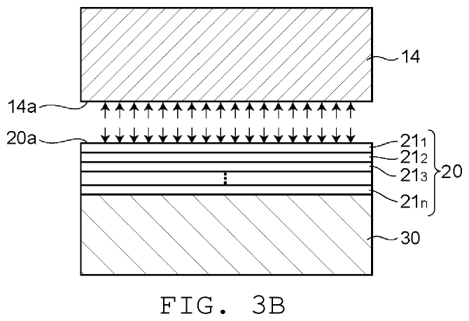

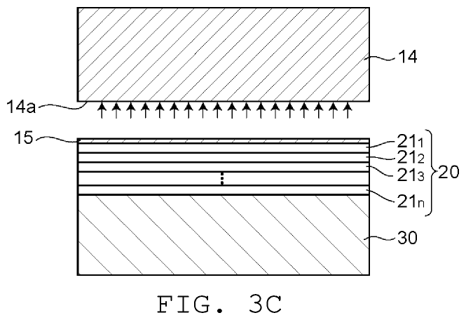

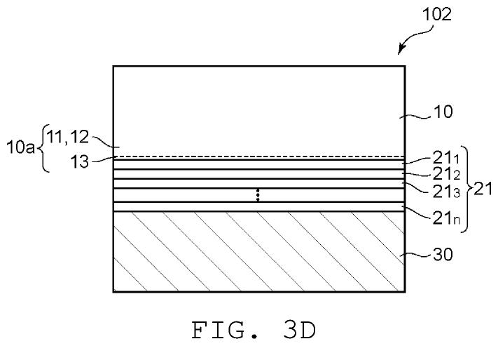

FIG. 3A to FIG. 3D are each a view for illustrating an example of a production process for a composite substrate according to one embodiment. FIG. 3A is an illustration of a state in which “n” layers from the first refractive index layer 21₁ to the n-th refractive index layer 21ₙ which may form the first multilayer film 21 are formed on the substrate 30 in the stated order from the n-th refractive index layer 21ₙ to form a laminated structure 20 of “n” layers on the substrate 30.

Next, the laminated structure 20 and a wavelength conversion material substrate 14 are directly joined to each other. At the time of the direct joining, it is preferred to activate each of the laminated structure 20 and the wavelength conversion material substrate 14 by any appropriate activation treatment.

The activation treatment is typically performed by irradiating the surface with a neutralized beam. The activation treatment is preferably performed by generating the neutralized beam with an apparatus such as an apparatus as described in JP 2014-086400 A, and irradiating g the surface with the beam. Specifically, a saddle-field fast atom beam (FAB) source is used as a beam source, and an inert gas, such as argon or xenon, is introduced into the chamber of the source, followed by the application of a high voltage from a DC power source thereof to an electrode thereof. Thus, a saddle-field electric field is generated between the electrode (positive electrode) and the casing (negative electrode) thereof to cause electron motion, to thereby generate the beams of an atom and an ion by the inert gas. Of the beams that have reached the grid of the apparatus, an ion beam is neutralized by the grid, and hence the beam of a neutral atom is emitted from the fast atom beam source. The voltage at the time of the beam irradiation is preferably set to from 0.5 kV to 2.0 kV, and a current at the time of the beam irradiation is preferably set to from 50 mA to 200 mA.

In one embodiment, the activation treatment may be performed in two stages. FIG. 3B is an illustration of a state in which each of a surface 20a of the laminated structure 20 and a surface 14a of the wavelength conversion material substrate 14 is subjected to first activation treatment. Typically, activation of the surface 20a of the laminated structure 20 and activation of the surface 14a of the wavelength conversion material substrate 14 may be performed at the same time. The length of time of the first activation treatment (e.g., the length of time of the beam irradiation described above) is preferably from 10 seconds to 30 seconds.

FIG. 3C is an illustration of second activation treatment. In the second activation treatment, the surface 14a of the wavelength conversion material substrate 14 is subjected to further beam irradiation. At this point, the laminated structure 20 side is subjected to substantially no beam irradiation. Through the second activation treatment, a deposition layer 15 containing a component for forming the wavelength conversion material substrate 14 may be formed on the surface of the laminated structure 20. Accordingly, the second activation treatment may be recognized as sputtering treatment. The second activation treatment (sputtering treatment) is performed by, for example, stopping the beam irradiation on the laminated structure 20 after the laminated structure 20 and the wavelength conversion material substrate 14 are irradiated with the beams in the first activation treatment, and continuing the beam irradiation on the wavelength conversion material substrate 14 further for a predetermined length of time. The length of time of the second activation treatment (sputtering treatment) (e.g., the length of time of the beam irradiation) is, for example, from 3 minutes to 10 minutes, preferably from 4 minutes to 7 minutes.

The deposition layer 15 may be an amorphous layer. A thickness of the deposition layer 15 is preferably from 0.2 nm to 8 nm, more preferably from 0.3 nm to 4 nm. As described above, the deposition layer 15 may contain a component for forming the wavelength conversion material substrate 14. The deposition layer 15 may also contain an inert gas atom. The deposition layer 15 may correspond to the third layer 13 of the composite substrate to be obtained.

The direct joining is performed by, after the activation treatment, bringing the deposition layer 15 formed in the laminated structure 20 and the wavelength conversion material substrate 14 into contact with each other, and applying a pressure to the resultant. Thus, a joined body (composite substrate) 102 illustrated in FIG. 3D is obtained. The contact and the application of a pressure are preferably performed in a vacuum atmosphere. A temperature at this time is typically normal temperature. Specifically, the temperature is preferably 20° C. or more and 40° C. or less, more preferably 25° C. or more and 30° C. or less. A pressure to be applied is preferably from 100 N to 20,000 N.

The broken line in FIG. 3D indicates a joining interface. The joining interface may be positioned inside the wavelength conversion layer 10. In the wavelength conversion layer 10, three layers (the first layer 11, the second layer 12, and the third layer 13) are formed near the joining interface. The first layer 11 contains, for example, substantially no inert gas atoms used in the activation treatment. The second layer 12 is positioned closer to the first multilayer film 21 than the first layer 11 is, and may contain an inert gas atom. The third layer 13 is in contact with the first multilayer film 21, and may be or may not contain an inert gas atom. Abundances of an inert gas atom in those layers are as described above. The first layer 11 may be formed of a crystalline body of the wavelength conversion material. The third layer 13 may be an amorphous layer obtained by amorphization of the wavelength conversion material. The second layer 12 may be formed of a crystalline body of the wavelength conversion material, or from an amorphous body obtained by amorphization of the wavelength conversion material, or may be a combination thereof.

When the joining interface is positioned inside the wavelength conversion layer 10, an influence of the activation treatment on the laminated structure 20 for which highly precise control of refractive indices may be required can be made extremely small. Specifically, an inert gas atom to be used for the activation treatment is substantially absent in the first refractive index layer (an outermost layer of the laminated structure 20) of the multilayer film, and mixing-in of the wavelength conversion material due to the activation treatment, generation of an amorphous structure (e.g., amorphous region containing an inert gas atom) due to the activation treatment, and the like can accordingly be suppressed. As a result, the first refractive index layer can have a desired refractive index and, for example, a desired reflection characteristic as an entire multilayer film can be satisfactorily achieved. In addition, mixing of impurities (e.g., Fe, Cr, or the like for forming a jig and a seat portion of an activation treatment apparatus) into the first refractive index layer (the outermost layer of the laminated structure 20) of the multilayer film can also be suppressed. The impurities may affect, for example, a transmittance of the multilayer film. Further, generation of an amorphous layer that accompanies the joining can be suppressed. Specifically, a thickness of the amorphous layer generated in accordance with the joining can be reduced.

After the direct joining, the joined body 102 may be subjected to annealing treatment. Specifically, the joined body 102 may be heated. When the annealing treatment is performed, the inert gas atom and the above-mentioned impurities can be volatilized through diffusion. In addition, crystallization of a portion in an amorphous state is also expected from the annealing treatment, and, for example, a further improvement of the reflection characteristic can be expected. A temperature of the annealing treatment (heating temperature) is, for example, from 300° C. to 450° C.

At the time of the joining, the surface of each of the laminated structure 20 and the wavelength conversion material substrate 14 is preferably a flat surface. Specifically, the arithmetic mean roughness Ra of the surfaces of the laminated structure 20 and the wavelength conversion material substrate 14 is preferably 5 nm or less, more preferably 2 nm or less, still more preferably 1 nm or less, particularly preferably 0.3 nm or less. A method of flattening the surface is, for example, mirror polishing through chemical-mechanical polishing (CMP) or lap polishing.

At the time of the film formation and the joining described above, the surface of each layer is preferably washed in order to, for example, remove the residue of a polishing agent. A method for the washing is, for example, wet washing, dry washing, or scrub washing. Of those, scrub washing is preferred because the surface can be simply and efficiently washed. A specific example of the scrub washing is a method including washing the surface in a scrub washing machine with a detergent (e.g., a SUNWASH series manufactured by Lion Corporation) and then with a solvent (e.g., a mixed solution of acetone and isopropyl alcohol (IPA)).

In FIGS. 3, the production of a joined body of the wavelength conversion layer 10 and the first multilayer film 21 by forming the laminated structure 20 on the substrate 30 is illustrated. In the same manner as in the example illustrated in FIGS. 3, a joined body of the wavelength conversion layer 10 and the second multilayer film 22 can be obtained by forming the laminated structure 20 on the function layer 40 and joining the resultant to the wavelength conversion material substrate 14. In a case of obtaining the composite substrate illustrated in FIG. 1, an order in which the substrate 30 and the function layer 40 are laminated onto the wavelength conversion material substrate 14 is not particularly limited. Specifically, the function layer 40 may be joined to the wavelength conversion material substrate 14 after the substrate 30 is joined to the wavelength conversion material substrate 14, or the substrate 30 may be joined to the wavelength conversion material substrate 14 after the function layer 40 is joined to the wavelength conversion material substrate 14.

### EXAMPLES

The present disclosure is specifically described below by way of Examples. However, the present disclosure is not limited by these Examples.

### Example 1

A tantalum oxide (Ta₂O₅) layer, a silicon oxide (SiO₂) layer, and an aluminum oxide (Al₂O₃) layer are formed on a substrate (GaAs substrate) in the order and thicknesses shown in Table 1 to form a laminated structure having twenty-nine refractive index layers in total. An Yb:YAG substrate is joined to the laminated structure by the method illustrated in FIG. 3 to provide a composite substrate. Refractive indices of the respective layers of the composite substrate are summarized in Table 1.

As shown in Table 1, the influence of the activation treatment (beam irradiation) on the first refractive index layer (tantalum oxide layer) is extremely small, and a desired refractive index is obtained.

### Comparative Example 1

A tantalum oxide (Ta₂O₅) layer, a silicon oxide (SiO₂) layer, and an aluminum oxide (Al₂O₃) layer are formed on a substrate (GaAs substrate) in the same manner as in Example 1 to form a laminated structure having twenty-nine refractive index layers in total. An Yb:YAG substrate is joined to the laminated structure in the same manner as in Example 1 except that, in the second activation treatment by the method illustrated in FIGS. 3, beam irradiation on the laminated structure was not stopped, to thereby obtain a composite substrate. Refractive indices of the respective layers of the composite substrate are summarized in Table 1.

As shown in Table 1, on an Yb:YAG layer side of the first refractive index layer (tantalum oxide layer), a layer (thickness: 50 nm) having a refractive index lower than the refractive index (2.23) of the tantalum oxide is formed by the activation treatment (beam irradiation). It can be recognized that, in this layer (region), there are components for forming YAG.

TABLE 1

| | | | | | Comparative Example 1 | |
|---|---|---|---|---|---|---|
| | | | Example 1 | | | |
| Composite substrate | | | Refractive | Thickness | Refractive | Thickness |
| | | | index | (nm) | index | (nm) |
| Wavelength conversion layer | | | | | | |
| | | Yb:YAG | 1.83 | - | 1.83 | - |
| Refractive | 1 | | 2.23 | 200 | 2.00 | 50 |
| index | | | | | 2.23 | 150 |
| layer | 2 | SiO₂ | 1.46 | 290 | 1.46 | 290 |
| | 3 | Ta₂O₅ | 2.23 | 240 | 2.23 | 240 |
| | 4 | SiO2 | 1.46 | 175 | 1.46 | 175 |
| | 5 | Ta₂O₅ | 2.23 | 110 | 2.23 | 110 |
| | 6 | SiO2 | 1.46 | 260 | 1.46 | 260 |
| | 7 | Ta₂O₅ | 2.23 | 125 | 2.23 | 125 |
| | 8 | SiO2 | 1.46 | 194 | 1.46 | 194 |
| | 9 | Ta₂O₅ | 2.23 | 114 | 2.23 | 114 |
| | 10 | SiO2 | 1.46 | 211 | 1.46 | 211 |
| | 11 | Ta₂O₅ | 2.23 | 96 | 2.23 | 96 |
| | 12 | SiO2 | 1.46 | 201 | 1.46 | 201 |
| | 13 | Ta₂O₅ | 2.23 | 125 | 2.23 | 125 |
| | 14 | SiO2 | 1.46 | 179 | 1.46 | 179 |
| | 15 | Ta₂O₅ | 2.23 | 125 | 2.23 | 125 |
| | 16 | SiO2 | 1.46 | 196 | 1.46 | 196 |
| | 17 | Ta₂O₅ | 2.23 | 125 | 2.23 | 125 |
| | 18 | SiO2 | 1.46 | 206 | 1.46 | 206 |
| | 19 | Ta₂O₅ | 2.23 | 106 | 2.23 | 106 |
| | 20 | SiO2 | 1.46 | 210 | 1.46 | 210 |
| | 21 | Ta₂O₅ | 2.23 | 124 | 2.23 | 124 |
| | 22 | SiO2 | 1.46 | 208 | 1.46 | 208 |
| | 23 | Ta₂O₅ | 2.23 | 95 | 2.23 | 95 |
| | 24 | SiO2 | 1.46 | 216 | 1.46 | 216 |
| | 25 | Al₂O₃ | 1.63 | 105 | 1.63 | 105 |
| | 26 | SiO2 | 1.46 | 216 | 1.46 | 216 |
| | 27 | Al₂O₃ | 1.63 | 237 | 1.63 | 237 |
| | 28 | SiO2 | 1.46 | 90 | 1.46 | 90 |
| | 29 | Ta₂O₅ | 2.23 | 62 | 2.23 | 62 |

| | | | | | |
|---|---|---|---|---|---|
| Substrate | GaAs | 3.40 | 4,842 | 3.4 | 4,842 |

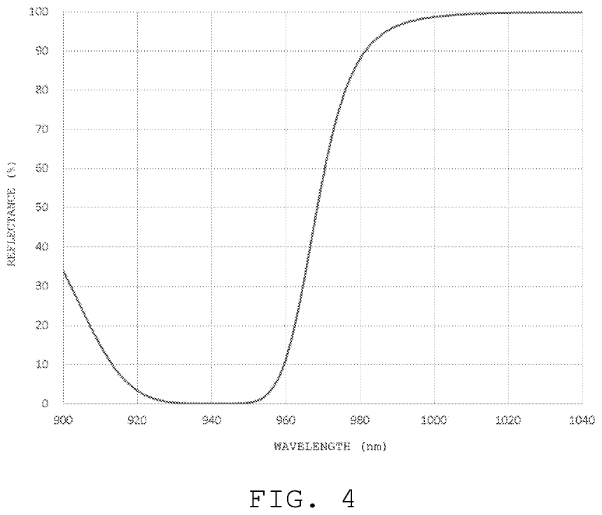

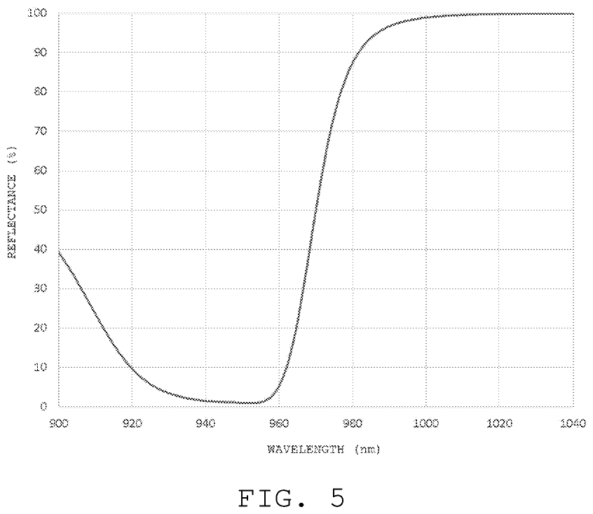

A simulation result of a reflection characteristic of a multilayer film in Example 1 is shown in FIG. 4, and a simulation result of a reflection characteristic of a multilayer film in Comparative Example 1 is shown in FIG. 5.

Yb:YAG has an effective excitation wavelength of from 935 nm to 945 nm, and is capable of conversion to light having a wavelength of 1,030 nm. The multilayer films in Example 1 and Comparative Example 1 transmit light having a wavelength that is the effective excitation wavelength of the wavelength conversion layer (Yb:YAG layer), and are capable of suppressing emission of light having a wavelength of 1,030 nm to be emitted from the wavelength conversion layer (Yb:YAG layer).

While the multilayer film in Example 1 had a reflectance of 0.1% at a wavelength of 940 nm, the multilayer film in Comparative Example 1 had a reflectance of 1.5% at a wavelength of 940 nm. It can be said from this that the multilayer film in Example 1 is more effective in terms of incidence of light having a wavelength that is the effective excitation wavelength of the wavelength conversion layer (Yb:YAG layer).

### (Composition Analysis of Example 1)

On a GaAs substrate, layers from the twenty-ninth refractive index layer to the second refractive index layer shown in Table 1 were sequentially formed in materials and thicknesses shown in Table 1. Then, lastly, a tantalum oxide layer (the first refractive index layer) having a thickness of 200 nm was formed to form a laminated structure having twenty-nine refractive index layers in total.

Next, a surface of an Yb:YAG substrate (YAG crystal) and a surface (tantalum oxide layer side) of the GaAs substrate on which the laminated structure had been formed were washed. The two substrates were then loaded into a vacuum chamber, a vacuum on the order of 10-6 Pa was reached by vacuuming, and the surfaces of the two substrates were simultaneously irradiated for 15 seconds with FABs (acceleration voltage: 1 kV, Ar flow rate: 27 sccm) that use Ar gas. The FAB irradiation was then stopped on the GaAs substrate side, whereas the FAB irradiation was continued on the Yb:YAG substrate side for 285 seconds longer.

Next, the GaAs substrate and the Yb:YAG substrate were directly joined to each other. Specifically, the surfaces of the two substrates that had been irradiated with FABs on top of one another were superimposed on each other, and both the surfaces were joined to each other by applying a pressure thereto at 10,000 N for 2 minutes at normal temperature to provide a joined body as illustrated in each of FIG. 2 and FIG. 3D.

The resultant joined body was then subjected to annealing treatment. Specifically, the resultant joined body was placed in a high-temperature furnace, and in this state, the temperature in the high-temperature furnace was increased from room temperature to a temperature higher than 100° C., followed by maintaining for a certain period of time. After that, the temperature was returned to room temperature to perform annealing.

In order to measure contents (abundances) of Ar in the respective layers for forming the joined body, surfaces of the respective layers were exposed by thinning the joined body by a focused ion beam (FIB) method, and energy dispersive X-ray analysis (EDX) was performed. Specifically, the analysis was performed by STEM-EDX observation using an atomic resolution analytical electron microscope (manufactured by JEOL Ltd., JEM-ARM200F Dual-X) and an energy dispersive X-ray analyzer (manufactured by JEOL Ltd., JED-2300) with an acceleration voltage of 200 kV and a beam spot size of about 0.2 nmΦ.

Measurement results are given below. An Ar content refers to the proportion of Ar atoms to all atoms present at a measurement site.
Measurement site 1 (YAG crystal corresponding to the first layer 11): 0 at %
Measurement site 2 (second layer 12): 2 at %
Measurement site 3 (third layer 13): 1 at %
Measurement site 4: (tantalum oxide layer corresponding to the first refractive index layer 21₁): 0.4 at %

### Example 2

A tantalum oxide (Ta₂O₅) layer, a silicon oxide (SiO₂) layer, and an aluminum oxide (Al₂O₃) layer are formed on a Cr:YAG substrate in the order and thicknesses shown in Table 2 to form a laminated structure having thirty-three refractive index layers in total. An Yb:YAG substrate is joined to the laminated structure by the method illustrated in FIG. 3 to provide a composite substrate. Refractive indices of the respective layers of the composite substrate are summarized in Table 2.

TABLE 2

| | | | Example 2 | |
|---|---|---|---|---|
| Composite substrate | | | Refractive | Thickness |
| Wavelength | | | index | (nm) |
| conversion layer | | Yb:YAG | 1.83 | — |
| Refractive | 1 | Ta₂O₅ | 2.23 | 160 |
| index layer | 2 | SiO₂ | 1.46 | 279 |
| | 3 | Al₂O₃ | 1.63 | 257 |
| | 4 | SiO₂ | 1.46 | 238 |
| | 5 | Ta₂O₅ | 2.23 | 259 |
| | 6 | SiO₂ | 1.46 | 260 |
| | 7 | Ta₂O₅ | 2.23 | 260 |
| | 8 | SiO₂ | 1.46 | 260 |
| | 9 | Ta₂O₅ | 2.23 | 260 |
| | 10 | SiO₂ | 1.46 | 260 |
| | 11 | Ta₂O₅ | 2.23 | 260 |
| | 12 | SiO₂ | 1.46 | 260 |
| | 13 | Ta₂O₅ | 2.23 | 260 |
| | 14 | SiO₂ | 1.46 | 260 |
| | 15 | Ta₂O₅ | 2.23 | 260 |
| | 16 | SiO₂ | 1.46 | 260 |
| | 17 | Ta₂O₅ | 2.23 | 260 |
| | 18 | SiO₂ | 1.46 | 260 |
| | 19 | Ta₂O₅ | 2.23 | 260 |
| | 20 | SiO₂ | 1.46 | 260 |
| | 21 | Ta₂O₅ | 2.23 | 260 |
| | 22 | SiO₂ | 1.46 | 260 |
| | 23 | Ta₂O₅ | 2.23 | 260 |
| | 24 | SiO₂ | 1.46 | 260 |
| | 25 | Ta₂O₅ | 2.23 | 260 |
| | 26 | SiO₂ | 1.46 | 260 |
| | 27 | Ta₂O₅ | 2.23 | 260 |
| | 28 | SiO₂ | 1.46 | 260 |
| | 29 | Al₂O₃ | 1.63 | 260 |
| | 30 | SiO₂ | 1.46 | 260 |
| | 31 | Ta₂O₅ | 2.23 | 190 |
| | 32 | Al₂O₃ | 1.63 | 260 |
| | 33 | SiO₂ | 1.46 | 75 |

| | | | |
|---|---|---|---|
| Function layer | Cr:YAG | 1.82 | 8,216 |

As shown in Table 2, the influence of the activation treatment (beam irradiation) on the first refractive index layer (tantalum oxide layer) is extremely small, and a desired refractive index is obtained.

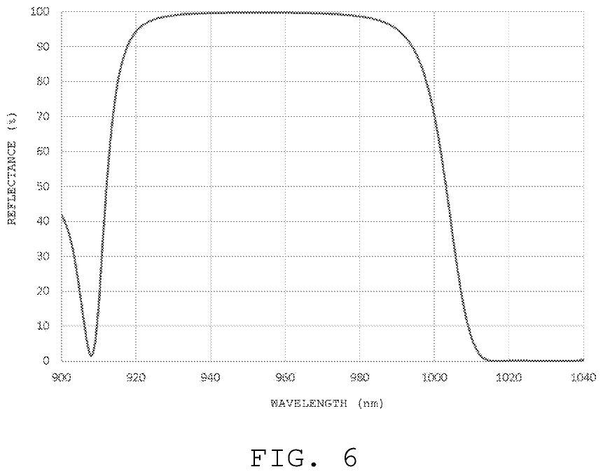

A simulation result of a reflection characteristic of a multilayer film in Example 2 is shown in FIG. 6.

The multilayer film in Example 2 transmits light having a wavelength of 1,030 nm to be emitted from the wavelength conversion layer (Yb:YAG layer), and is capable of suppressing emission of light having a wavelength that is the effective excitation wavelength of the wavelength conversion layer (Yb:YAG layer).

### Example 3

A mixed crystal layer of titanium oxide (TiO₂) and zirconium oxide (ZrO₂), a silicon oxide (SiO₂) layer, and an aluminum oxide (Al₂O₃) layer are formed on a substrate (GaAs substrate) in the order and thicknesses shown in Table 3 to form a laminated structure having twenty-nine refractive index layers in total. An Yb:YAG substrate is joined to the laminated structure by the method illustrated in FIG. 3 to provide a composite substrate. Refractive indices of the respective layers of the composite substrate are summarized in Table 3. The mixed crystal layer of titanium oxide and zirconium oxide can be formed by sputtering using a target containing a mixed crystal of titanium oxide and zirconium oxide in advance.

TABLE 3

| Composite substrate | | | Example 3 | |
|---|---|---|---|---|
| Wavelength | | | Refractive | Thickness |
| conversion | | | index | (nm) |
| layer | | Yb:YAG | 1.83 | — |
| | 1 | TiO₂ + ZrO₂ | 2.22 | 200 |
| | 2 | SiO₂ | 1.46 | 290 |
| | 3 | TiO₂ + ZrO₂ | 2.22 | 240 |
| | 4 | SiO₂ | 1.46 | 175 |
| | 5 | TiO₂ + ZrO₂ | 2.22 | 110 |
| | 6 | SiO₂ | 1.46 | 260 |
| | 7 | TiO₂ + ZrO₂ | 2.22 | 125 |
| | 8 | SiO₂ | 1.46 | 194 |
| | 9 | TiO₂ + ZrO₂ | 2.22 | 114 |
| | 10 | SiO₂ | 1.46 | 211 |
| | 11 | TiO₂ + ZrO₂ | 2.22 | 96 |
| | 12 | SiO₂ | 1.46 | 201 |
| | 13 | TiO₂ + ZrO₂ | 2.22 | 125 |
| | 14 | SiO₂ | 1.46 | 179 |
| | 15 | TiO₂ + ZrO₂ | 2.22 | 125 |
| | 16 | SiO₂ | 1.46 | 196 |
| | 17 | TiO₂ + ZrO₂ | 2.22 | 125 |
| | 18 | SiO₂ | 1.46 | 206 |
| | 19 | TiO₂ + ZrO₂ | 2.22 | 106 |
| | 20 | SiO₂ | 1.46 | 210 |
| | 21 | TiO₂ + ZrO₂ | 2.22 | 124 |
| | 22 | SiO₂ | 1.46 | 208 |
| | 23 | TiO₂ + ZrO₂ | 2.22 | 95 |
| | 24 | SiO₂ | 1.46 | 216 |
| | 25 | Al₂O₃ | 1.63 | 105 |
| | 26 | SiO₂ | 1.46 | 216 |
| | 27 | Al₂O₃ | 1.63 | 237 |
| | 28 | SiO₂ | 1.46 | 90 |
| | 29 | TiO₂ + ZrO₂ | 2.22 | 62 |

| | | | |
|---|---|---|---|
| Substrate | GaAs | 3.40 | 4,842 |

As shown in Table 3, the influence of the activation treatment (beam irradiation) on the first refractive index layer (mixed crystal layer of titanium oxide and zirconium oxide) is extremely small, and a desired refractive index is obtained.

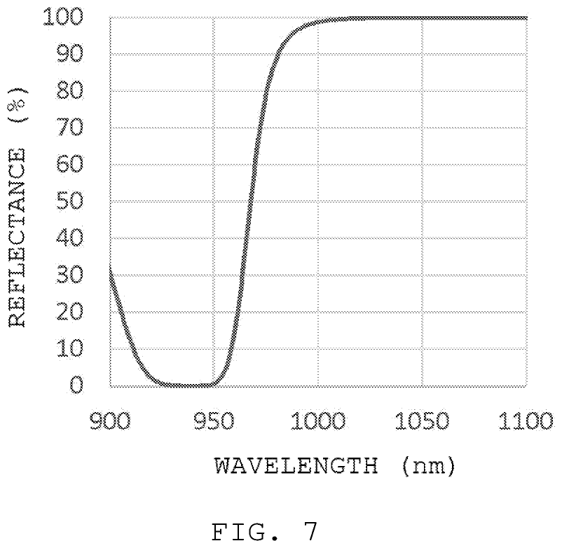

A simulation result of a reflection characteristic of a multilayer film in Example 3 is shown in FIG. 7.

Yb:YAG has an effective excitation wavelength of from 935 nm to 945 nm, and is capable of conversion to light having a wavelength of 1,030 nm. The multilayer film in Example 3 transmits light having a wavelength that is the effective excitation wavelength of the wavelength conversion layer (Yb:YAG layer), and is capable of suppressing emission of light having a wavelength of 1,030 nm to be emitted from the wavelength conversion layer (Yb:YAG layer). The multilayer film in Example 3 had a reflectance of 0.1% at a wavelength of 940 nm.

### Example 4

A magnesium oxide (MgO) layer, a tantalum oxide (Ta₂O₅) layer, a silicon oxide (SiO₂) layer, and an aluminum oxide (Al₂O₃) layer are formed on a substrate (GaAs substrate) in the order and thicknesses shown in Table 4 to form a laminated structure having twenty-nine refractive index layers in total. An Yb:YAG substrate is joined to the laminated structure by the method illustrated in FIG. 3 to provide a composite substrate. Refractive indices of the respective layers of the composite substrate are summarized in Table 4.

TABLE 4

| Composite substrate | | | Example 4 | |
|---|---|---|---|---|
| Wavelength | | | Refractive | Thickness |
| conversion | | | index | (nm) |
| layer | | Yb:YAG | 1.83 | — |
| | 1 | MgO | 1.74 | 266 |
| | 2 | SiO₂ | 1.46 | 286 |
| | 3 | MgO | 1.74 | 267 |
| | 4 | SiO₂ | 1.46 | 189 |
| | 5 | MgO | 1.74 | 80 |
| | 6 | SiO₂ | 1.46 | 237 |
| | 7 | MgO | 1.74 | 174 |
| | 8 | SiO₂ | 1.46 | 199 |
| | 9 | MgO | 1.74 | 124 |
| | 10 | SiO₂ | 1.46 | 226 |
| | 11 | Ta₂O₅ | 2.23 | 106 |
| | 12 | SiO₂ | 1.46 | 201 |
| | 13 | Ta₂O₅ | 2.23 | 126 |
| | 14 | SiO₂ | 1.46 | 180 |
| | 15 | Ta₂O₅ | 2.23 | 126 |
| | 16 | SiO₂ | 1.46 | 197 |
| | 17 | Ta₂O₅ | 2.23 | 126 |
| | 18 | SiO₂ | 1.46 | 206 |
| | 19 | Ta₂O₅ | 2.23 | 107 |
| | 20 | SiO₂ | 1.46 | 211 |
| | 21 | Ta₂O₅ | 2.23 | 124 |
| | 22 | SiO₂ | 1.46 | 209 |
| | 23 | Ta₂O₅ | 2.23 | 95 |
| | 24 | SiO₂ | 1.46 | 217 |
| | 25 | Al₂O₃ | 1.63 | 105 |
| | 26 | SiO₂ | 1.46 | 217 |
| | 27 | Al₂O₃ | 1.63 | 238 |
| | 28 | SiO₂ | 1.46 | 89 |
| | 29 | Ta₂O₅ | 2.23 | 60 |

| | | | |
|---|---|---|---|
| Substrate | GaAs | 3.40 | 4,842 |

As shown in Table 4, the influence of the activation treatment (beam irradiation) on the first refractive index layer (magnesium oxide layer) is extremely small, and a desired refractive index is obtained.

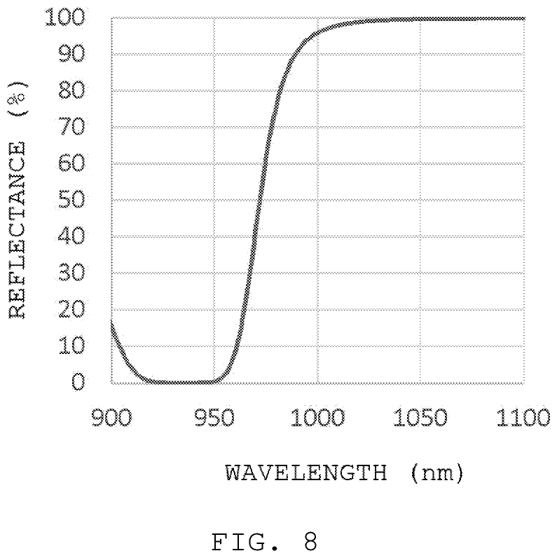

A simulation result of a reflection characteristic of a multilayer film in Example 4 is shown in FIG. 8.

Yb:YAG has an effective excitation wavelength of from 935 nm to 945 nm, and is capable of conversion to light having a wavelength of 1,030 nm. The multilayer film in Example 4 transmits light having a wavelength that is the effective excitation wavelength of the wavelength conversion layer (Yb:YAG layer), and is capable of suppressing emission of light having a wavelength of 1,030 nm to be emitted from the wavelength conversion layer (Yb:YAG layer). The multilayer film in Example 4 had a reflectance of 0.1% at a wavelength of 940 nm.

### Example 5

A mixed crystal layer of titanium oxide (TiO₂) and zirconium oxide (ZrO₂), a tantalum oxide (Ta₂O₅) layer, a silicon oxide (SiO₂) layer, and an aluminum oxide (Al₂O₃) layer are formed on a substrate (GaAs substrate) in the order and thicknesses shown in Table 5 to form a laminated structure having twenty-nine refractive index layers in total. An Yb:YAG substrate is joined to the laminated structure by the method illustrated in FIG. 3 to provide a composite substrate. Refractive indices of the respective layers of the composite substrate are summarized in Table 5.

TABLE 5

| Composite substrate | | | Example 5 | |
|---|---|---|---|---|
| Wavelength | | | Refractive | Thickness |
| conversion | | | index | (nm) |
| layer | | Yb:YAG | 1.83 | — |
| | 1 | Ta₂O₅ | 2.23 | 200 |
| | 2 | SiO₂ | 1.46 | 290 |
| | 3 | TiO₂ + ZrO₂ | 2.22 | 240 |
| | 4 | SiO₂ | 1.46 | 175 |
| | 5 | TiO₂ + ZrO₂ | 2.22 | 110 |
| | 6 | SiO₂ | 1.46 | 260 |
| | 7 | TiO₂ + ZrO₂ | 2.22 | 125 |
| | 8 | SiO₂ | 1.46 | 194 |
| | 9 | TiO₂ + ZrO₂ | 2.22 | 114 |
| | 10 | SiO₂ | 1.46 | 211 |
| | 11 | TiO₂ + ZrO₂ | 2.22 | 96 |
| | 12 | SiO₂ | 1.46 | 201 |
| | 13 | TiO₂ + ZrO₂ | 2.22 | 125 |
| | 14 | SiO₂ | 1.46 | 179 |
| | 15 | TiO₂ + ZrO₂ | 2.22 | 125 |
| | 16 | SiO₂ | 1.46 | 196 |
| | 17 | TiO₂ + ZrO₂ | 2.22 | 125 |
| | 18 | SiO₂ | 1.46 | 206 |
| | 19 | TiO₂ + ZrO₂ | 2.22 | 106 |
| | 20 | SiO₂ | 1.46 | 210 |
| | 21 | TiO₂ + ZrO₂ | 2.22 | 124 |
| | 22 | SiO₂ | 1.46 | 208 |
| | 23 | TiO₂ + ZrO₂ | 2.22 | 95 |
| | 24 | SiO₂ | 1.46 | 216 |
| | 25 | Al₂O₃ | 1.63 | 105 |
| | 26 | SiO₂ | 1.46 | 216 |
| | 27 | Al₂O₃ | 1.63 | 237 |
| | 28 | SiO₂ | 1.46 | 90 |
| | 29 | TiO₂ + ZrO₂ | 2.22 | 62 |

| | | | |
|---|---|---|---|
| Substrate | GaAs | 3.40 | 4,842 |

As shown in Table 5, the influence of the activation treatment (beam irradiation) on the first refractive index layer (tantalum oxide layer) is extremely small, and a desired refractive index is obtained.

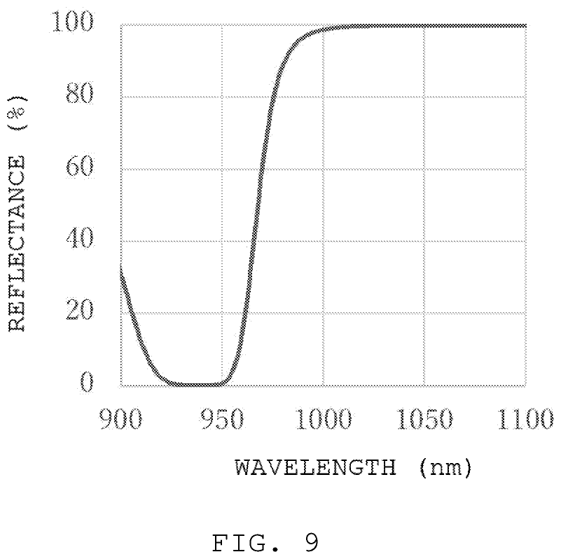

A simulation result of a reflection characteristic of a multilayer film in Example 5 is shown in FIG. 9.

Yb:YAG has an effective excitation wavelength of from 935 nm to 945 nm, and is capable of conversion to light having a wavelength of 1,030 nm. The multilayer film in Example 5 transmits light having a wavelength that is the effective excitation wavelength of the wavelength conversion layer (Yb:YAG layer), and is capable of suppressing emission of light having a wavelength of 1,030 nm to be emitted from the wavelength conversion layer (Yb:YAG layer). The multilayer film in Example 5 had a reflectance of 0.1% at a wavelength of 940 nm.

### Example 6

A titanium oxide (TiO₂) layer, a silicon oxide (SiO₂) layer, and an aluminum oxide (Al₂O₃) layer are formed on a substrate (GaAs substrate) in the order and thicknesses shown in Table 6 to form a laminated structure having twenty-nine refractive index layers in total. An Yb:YAG substrate is joined to the laminated structure by the method illustrated in FIG. 3 to provide a composite substrate. Refractive indices of the respective layers of the composite substrate are summarized in Table 6.

TABLE 6

| Composite substrate | | | Example 6 | |
|---|---|---|---|---|
| Wavelength | | | Refractive | Thickness |
| conversion | | | index | (nm) |
| layer | | Yb:YAG | 1.83 | — |
| | 1 | TiO₂ | 2.35 | 182 |
| | 2 | SiO₂ | 1.46 | 285 |
| | 3 | TiO₂ | 2.35 | 236 |
| | 4 | SiO₂ | 1.46 | 172 |
| | 5 | TiO₂ | 2.35 | 113 |
| | 6 | SiO₂ | 1.46 | 251 |
| | 7 | TiO₂ | 2.35 | 123 |
| | 8 | SiO₂ | 1.46 | 191 |
| | 9 | TiO₂ | 2.35 | 112 |
| | 10 | SiO₂ | 1.46 | 207 |
| | 11 | TiO₂ | 2.35 | 95 |
| | 12 | SiO₂ | 1.46 | 198 |
| | 13 | TiO₂ | 2.35 | 123 |
| | 14 | SiO₂ | 1.46 | 176 |
| | 15 | TiO₂ | 2.35 | 123 |
| | 16 | SiO₂ | 1.46 | 193 |
| | 17 | TiO₂ | 2.35 | 123 |
| | 18 | SiO₂ | 1.46 | 202 |
| | 19 | TiO₂ | 2.35 | 105 |
| | 20 | SiO₂ | 1.46 | 206 |
| | 21 | TiO₂ | 2.35 | 122 |
| | 22 | SiO₂ | 1.46 | 206 |
| | 23 | TiO₂ | 2.35 | 98 |
| | 24 | SiO₂ | 1.46 | 211 |
| | 25 | Al₂O₃ | 1.63 | 103 |
| | 26 | SiO₂ | 1.46 | 212 |
| | 27 | Al₂O₃ | 1.63 | 233 |
| | 28 | SiO₂ | 1.46 | 108 |
| | 29 | TiO₂ | 2.35 | 61 |

| | | | |
|---|---|---|---|
| Substrate | GaAs | 3.40 | 4,842 |

As shown in Table 6, the influence of the activation treatment (beam irradiation) on the first refractive index layer (titanium oxide layer) is extremely small, and a desired refractive index is obtained.

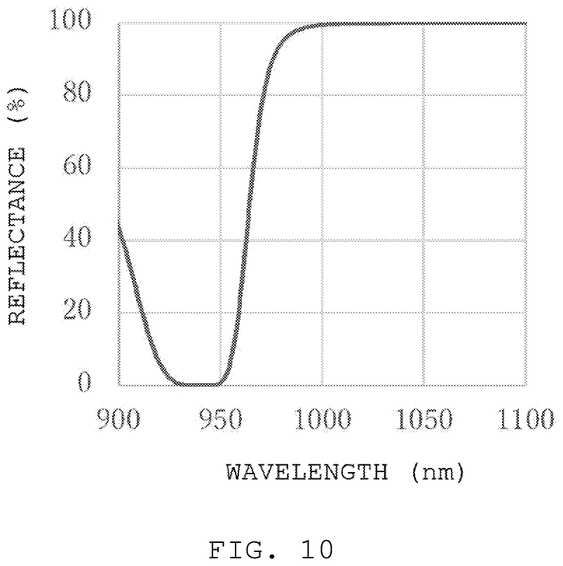

A simulation result of a reflection characteristic of a multilayer film in Example 6 is shown in FIG. 10.

Yb:YAG has an effective excitation wavelength of from 935 nm to 945 nm, and is capable of conversion to light having a wavelength of 1,030 nm. The multilayer film in Example 6 transmits light having a wavelength that is the effective excitation wavelength of the wavelength conversion layer (Yb:YAG layer), and is capable of suppressing emission of light having a wavelength of 1,030 nm to be emitted from the wavelength conversion layer (Yb:YAG layer). The multilayer film in Example 6 had a reflectance of 0.1% at a wavelength of 940 nm.

### Example 7

A tantalum oxide (Ta₂O₅) layer, a silicon oxide (SiO₂) layer, and an aluminum oxide (Al₂O₃) layer are formed on a substrate (GaAs substrate) in the order and thicknesses shown in Table 7 to form a laminated structure having twenty-nine refractive index layers in total. An Yb:YAG substrate is joined to the laminated structure by the method illustrated in FIG. 3 to provide a composite substrate. Refractive indices of the respective layers of the composite substrate are summarized in Table 7.

TABLE 7

| Composite substrate | | | Example 7 | |
|---|---|---|---|---|
| Wavelength | | | Refractive | Thickness |
| conversion | | | index | (nm) |
| layer | | Yb:YAG | 1.83 | — |
| | 1 | Al₂O₃ | 1.63 | 195 |
| | 2 | SiO₂ | 1.46 | 330 |
| | 3 | Al₂O₃ | 1.63 | 240 |
| | 4 | SiO₂ | 1.46 | 188 |
| | 5 | Al₂O₃ | 1.63 | 110 |
| | 6 | SiO₂ | 1.46 | 261 |
| | 7 | Ta₂O₅ | 2.23 | 149 |
| | 8 | SiO₂ | 1.46 | 200 |
| | 9 | Ta₂O₅ | 2.24 | 125 |
| | 10 | SiO₂ | 1.46 | 225 |
| | 11 | Ta₂O₅ | 2.23 | 106 |
| | 12 | SiO₂ | 1.46 | 201 |
| | 13 | Ta₂O₅ | 2.23 | 125 |
| | 14 | SiO₂ | 1.46 | 179 |
| | 15 | Ta₂O₅ | 2.23 | 125 |
| | 16 | SiO₂ | 1.46 | 196 |
| | 17 | Ta₂O₅ | 2.23 | 125 |
| | 18 | SiO₂ | 1.46 | 206 |
| | 19 | Ta₂O₅ | 2.23 | 106 |
| | 20 | SiO₂ | 1.46 | 210 |
| | 21 | Ta₂O₅ | 2.23 | 124 |
| | 22 | SiO₂ | 1.46 | 208 |
| | 23 | Ta₂O₅ | 2.23 | 95 |
| | 24 | SiO₂ | 1.46 | 216 |
| | 25 | Al₂O₃ | 1.63 | 105 |
| | 26 | SiO₂ | 1.46 | 216 |
| | 27 | Al₂O₃ | 1.63 | 237 |
| | 28 | SiO₂ | 1.46 | 92 |
| | 29 | Ta₂O₅ | 2.23 | 58 |

| | | | |
|---|---|---|---|
| Substrate | GaAs | 3.40 | 4,842 |

As shown in Table 7, the influence of the activation treatment (beam irradiation) on the first refractive index layer (aluminum oxide layer) is extremely small, and a desired refractive index is obtained.

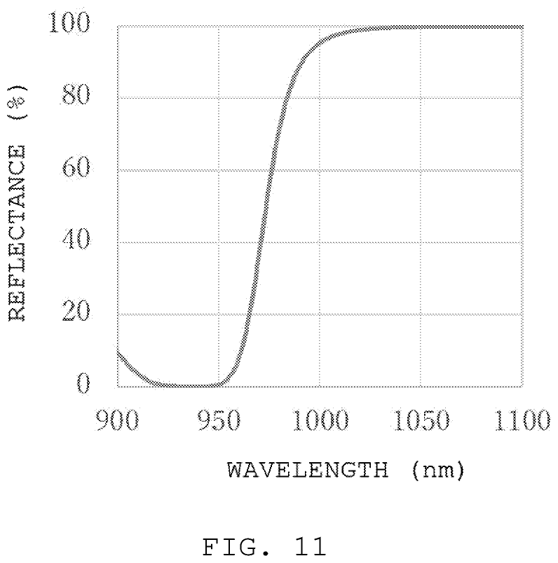

A simulation result of a reflection characteristic of a multilayer film in Example 7 is shown in FIG. 11.

Yb:YAG has an effective excitation wavelength of from 935 nm to 945 nm, and is capable of conversion to light having a wavelength of 1,030 nm. The multilayer film in Example 7 transmits light having a wavelength that is the effective excitation wavelength of the wavelength conversion layer (Yb:YAG layer), and is capable of suppressing emission of light having a wavelength of 1,030 nm to be emitted from the wavelength conversion layer (Yb:YAG layer). The multilayer film in Example 7 had a reflectance of 0.1% at a wavelength of 940 nm.

The composite substrate according to the embodiment of the present disclosure can be suitably used in laser devices for sensing, precision processing, medicine, and the like.

What is claimed is:

1. A composite substrate, comprising:
a wavelength conversion layer configured to convert incident light into light having a different wavelength; and
a multilayer film arranged adjacent to the wavelength conversion layer,
wherein the multilayer film includes a plurality of refractive index layers,
wherein the wavelength conversion layer has an end portion in a thickness direction on a side on which the multilayer film is arranged, and, in the end portion of the wavelength conversion layer in the thickness direction, a region in which an abundance of an inert gas atom is 0.5 at % or more is formed, and
wherein, in the multilayer film, a first refractive index layer is positioned closest to the wavelength conversion layer among the plurality of refractive index layers, and an abundance of the inert gas atom in the first refractive index layer is less than 0.5 at %.

2. The composite substrate according to claim 1,
wherein the plurality of refractive index layers included in the multilayer film each have a refractive index of from 1.3 to 2.4, and
wherein the multilayer film includes one or more refractive index layers each having a refractive index of 2.1 or more.

3. The composite substrate according to claim 1, wherein the wavelength conversion layer and the first refractive index layer are joined to each other.

4. The composite substrate according to claim 1, wherein the inert gas atom is argon or xenon.

5. The composite substrate according to claim 1, wherein, in the multilayer film, a difference between a highest refractive index and a lowest refractive index among refractive indices of the plurality of refractive index layers is 0.5 or more.

6. The composite substrate according to claim 1, wherein the wavelength conversion layer is selected from a doped yttrium aluminum garnet crystal, a doped yttrium vanadate crystal, and a doped yttrium lithium fluoride crystal.

7. The composite substrate according to claim 1, wherein, a material for forming each of the plurality of refractive index layers included in the multilayer film is selected from silicon oxide, tantalum oxide, titanium oxide, aluminum oxide, yttrium oxide, zirconium oxide, hafnium oxide, lanthanum oxide, cerium oxide, tungsten oxide, zinc oxide, niobium oxide, and magnesium oxide.

8. The composite substrate according to claim 1, wherein a material for forming the first refractive index layer is selected from tantalum oxide, titanium oxide, aluminum oxide, yttrium oxide, zirconium oxide, hafnium oxide, lanthanum oxide, cerium oxide, tungsten oxide, zinc oxide, niobium oxide, and magnesium oxide.

9. The composite substrate according to claim 1, wherein the end portion of the wavelength conversion layer in the thickness direction includes a third layer, a second layer, and a first layer in the stated order from the multilayer film side, and an abundance of the inert gas atom in the second layer is larger than an abundance of the inert gas atom in the third layer.

10. The composite substrate according to claim 9, wherein the third layer is an amorphous layer.

11. The composite substrate according to claim 1, wherein the first refractive index layer has a refractive index that is uniform in the thickness direction.

12. The composite substrate according to claim 1, wherein two neighboring refractive index layers included in the multilayer film have refractive indices different from each other.

13. The composite substrate according to claim 1, wherein the plurality of refractive index layers included in the multilayer film each have a thickness of 50 nm or more and 300 nm or less.

14. The composite substrate according to claim 1, wherein the composite substrate comprises the wavelength conversion layer, the multilayer film, and a surface emitting laser substrate in the stated order.

15. The composite substrate according to claim 1, wherein the composite substrate comprises the wavelength conversion layer, the multilayer film, and a saturable absorber layer in the stated order.

16. A composite substrate, comprising in the following order:
a surface emitting laser substrate;
a wavelength conversion layer configured to convert incident light into light having a different wavelength; and
a saturable absorber layer,
wherein the composite substrate further comprises multilayer film arranged adjacent to the wavelength conversion layer, in at least one of a space between the surface emitting laser substrate and the wavelength conversion layer or a space between the saturable absorber layer and the wavelength conversion layer,
wherein the multilayer film includes a plurality of refractive index layers,
wherein the wavelength conversion layer has an end portion in a thickness direction on a side on which the multilayer film is arranged, and, in the end portion of the wavelength conversion layer in the thickness direction, a region in which an abundance of an inert gas atom is 0.5 at % or more is formed, and
wherein, in the multilayer film, a first refractive index layer is positioned closest to the wavelength conversion layer among the plurality of refractive index layers, and an abundance of the inert gas atom in the first refractive index layer is less than 0.5 at %.

17. A laser structure, comprising the composite substrate of claim 1.

18. A method of producing the composite substrate of claim 1, the method comprising in the following order:
preparing a laminated structure having a plurality of refractive index layers;
subjecting each of a surface of a wavelength conversion material substrate and a surface of the laminated structure to activation treatment;
forming, on the surface of the laminated structure, a deposition layer containing a component for forming the wavelength conversion material substrate by subjecting the surface of the wavelength conversion material substrate to sputtering treatment; and
joining the laminated structure and the wavelength conversion material substrate to each other.

19. The method of producing the composite substrate according to claim 18, wherein a length of time of the sputtering treatment is from 3 minutes to 10 minutes.
